(19) United States
(12) Patent Application Publication
(10) Pub. No.: US 2009/0117289 A1
(43) Pub. Date: May 7, 2009

(54) Method and apparatus for deposition of thin film materials for energy storage devices

(75) Inventors: Elena M. Shembel, Coral Springs, FL (US); Valeriy Tutyk, Dnipropetrovsk (UA); Volodymyr Redko, Coral Springs, FL (US); Alexandr Markevich, Dnipropetrovsk (UA); Tymofiy Pastushkin, Ft. Lauderdale, FL (US); Irina Maksyuta, Dnipropetrovsk (UA)

Correspondence Address: Enerize Corporation;Elena Shembel, 4956 Rothschild Dr., Coral Springs, FL, 33067-4134, US

(73) Assignee: Enerize Corporation, Coral Springs, FL (US)

(21) Appl. No.: 12/287,397

(22) Filed: Oct. 9, 2008

Related U.S. Application Data
(60) Provisional application No. 60/998,379, filed on Oct. 9, 2007.

(51) Int. Cl. C23C 16/513

(52) U.S. Cl. 427/569; 118/715

(57) ABSTRACT

The present invention is a method and apparatus for applying coatings in a rarefied gaseous medium. A cold cathode electron gun is used to generate an electron beam, which is directed to a crucible containing initial solid materials in a vacuum chamber, thus generating an initial solid material vapor. Nitrogen reaction gas is bled into the vacuum chamber, and ionization of the nitrogen gas in high frequency discharge. Subsequent interaction of initial material vapor with nitrogen ions and atoms results in generation of solid product heating of the substrate. Condensation of the vapor on the surface of substrate generates a thin film of solid electrode or electrolyte. The resulting rate of deposition of thin film of vitreous solid electrolyte and LiPon solid electrolyte is substantially higher than can be achieved with a magnetron sputtering process.

### BACKGROUND

Use of thin film electrodes and solid inorganic electrolytes (SE) will enable design of a new generation of lithium batteries, including micro-batteries, with the capability for safe charging/cycling, a wide operating temperature range, and new standard sizes.

More valuable methods of deposition for thin films of solid electrolyte must combine high efficiency (high rates of deposition), the capability to manage the properties of the deposited material during the process, and the availability of the necessary equipment.

The present invention allows an increased rate of deposition of thin films of vitreous solid electrolyte and Lipon solid electrolyte as compared with the magnetron sputtering processes.

### BRIEF DESCRIPTION OF THE INVENTION

To develop a thin film of vitreous solid electrolyte and a thin film of Lipon, a gas discharge electron gun with a cold cathode is used. This allows an increased rate of deposition of thin films of vitreous solid electrolyte and Lipon solid electrolyte as compared with the magnetron sputtering process.

### DESCRIPTION OF THE DRAWINGS

Shown in the drawings are presently preferred embodiments. It will be understood, however, that the invention can be embodied in other forms without departing from the spirit or essential attributes thereof.

FIG. 1. Illustrates the scheme of the process for coating in a vacuum or rarified gas environment according to the present invention.

FIG. 2. Prototype apparatus built for practice of the process of the present invention is shown schematically. Elements of the invention designated in the schematic are as follows:
201—vacuum chamber (VC),
202—electronic gun (EG),
203—the system focusing and deflecting the electron beam (FDS);
204—electron beam (ER);
205—crucible containing the substance to be vaporized (C);
206—heater with a substrate and thermocouple (H);
207—high-voltage power-supply source (HPSS);
208—power supply unit for the focusing and deflecting system (PSU FDS);
209—power-supply source for the heater of the substrate (PSSH);
210—-substrate-temperature meter(TM1)
211—crucible-temperature meter (TM2);
212—pump-off vacuum system (PVS);
213—gas-pressure meter (GPM);
214—gas-feeding system (GFS);
215—water cooling-system (CS)

FIG. 3. Vapor pressure Pᵥ in a vapor pressure gradient during cathode-ray vaporization.

FIG. 4. Scheme of a crucible for vaporization of lithium orthophosphate where 401 is lithium orthophosphate substance being vaporized; 402 is a ceramic crucible; 403 is a metal stainless-steel crucible; 404 is a metal radiator; 405 is a thermocouple; and 406 is a stainless-steel base.

FIG. 5. a, b, c. Apparatus for ion-plating with a cathode-ray vaporization: 501, 507, 512 is a vacuum chamber, 502, 508, 513 is a gas-discharge electron gun; 503 is a substrate which is electrically insulated from the ground; 504 is an electron beam; 505 is a ring-shaped anode; 506, 511, 516 is a crucible containing lithium orthophosphate; 510, 515 is deflecting magnet that generate the additional magnetic field for turning the electrone bean. The following power sources are used in the scheme:
U_{A} is a high-voltage current source for the electron gun;
Uᵤ is a power source for vapor and gas ionization close to the crucible;
U_{CM} is a power source to accelerate ions from the crucible to the substrate.

FIG. 6. XRD data from a sample of LiPon on a glass support. Thickness of the LiPon is 20 microns.

FIG. 7. XRD of the powder that was generated by evaporation of the Li₃PO₄ in pure Argon.

FIG. 8. Impedance characteristics of the Pt (801) and Pt with deposited LiPon (802). Thickness of the LiPon is 2 micron. Operating range of the frequency is from 1 kHz to 100 kHz.

FIG. 9. Potentiometric (cyclic voltametry) characteristics of the Pt electrode in non-aqueous electrolyte FIG. 10. Potentiometric (cyclic voltametry) characteristics of the Pt electrode covered with deposited LiPon in non-aqueous electrolyte. Thickness of the LiPon is 2 microns.

### DETAILED DESCRIPTION OF THE INVENTION

The overall process of vaporization of lithium orthophosphate with electron beam and subsequent formation of a LiPon coating on the substrate can be divided into three stages:
1) vaporization of lithium orthophosphate with an electron beam;
2) transfer of lithium vapor to the substrate in a nitrogen medium;
3) condensation of the lithium orthophosphate vapor on the substrate.

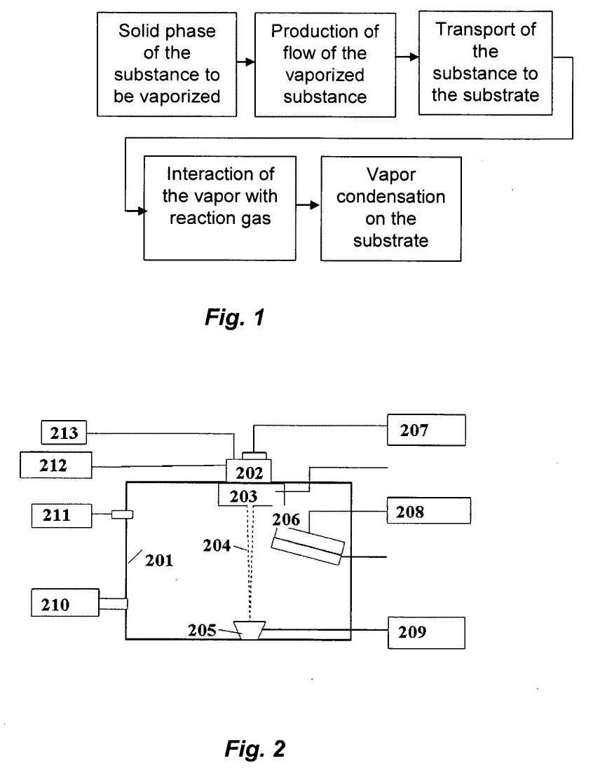

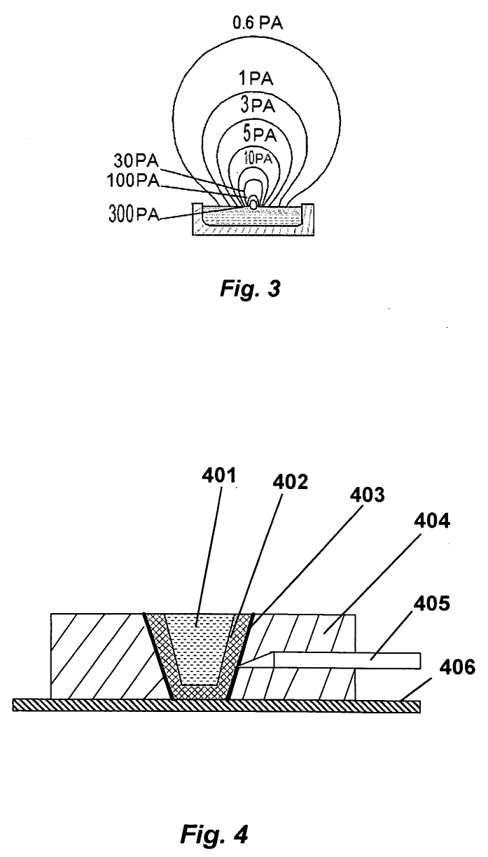

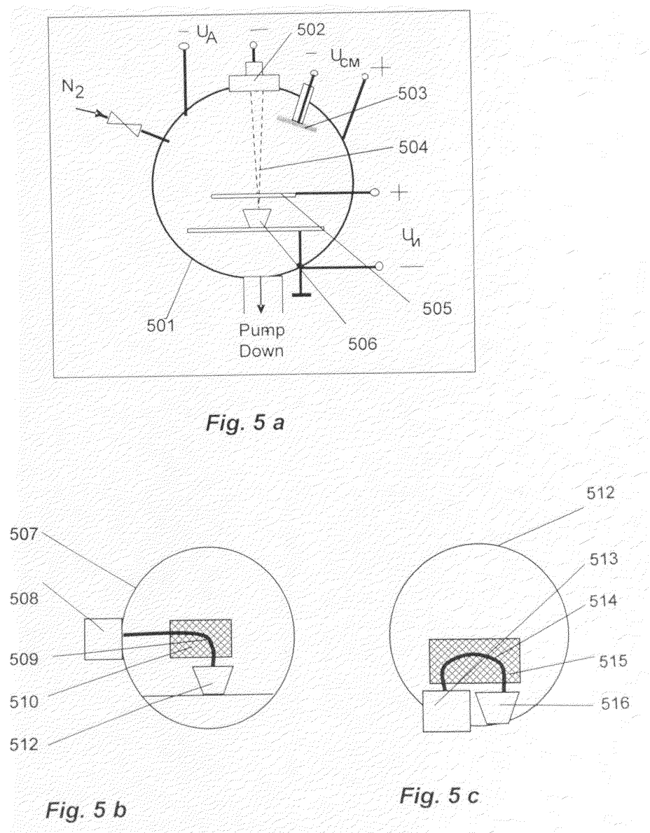

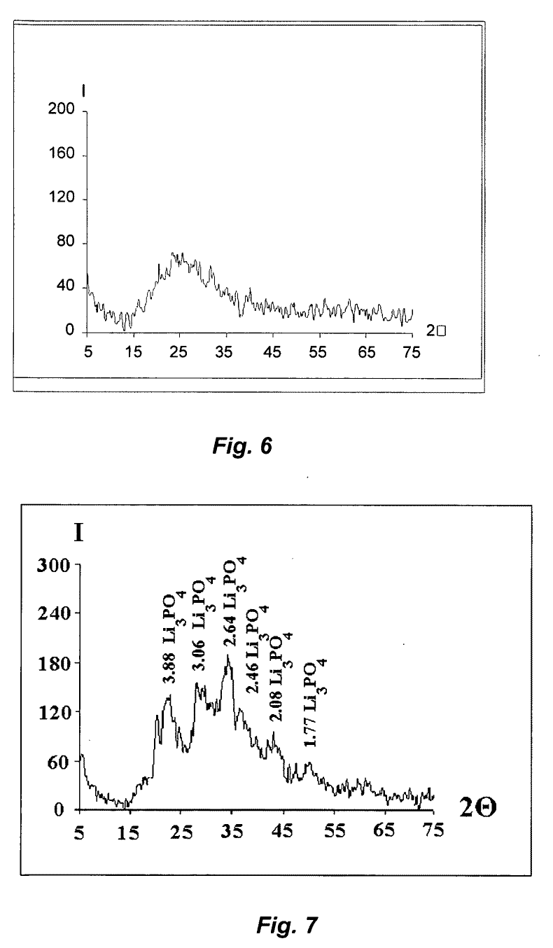

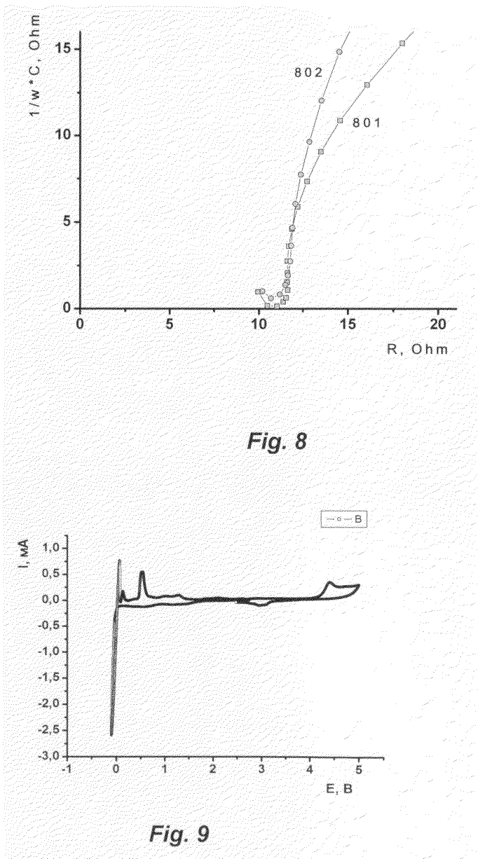

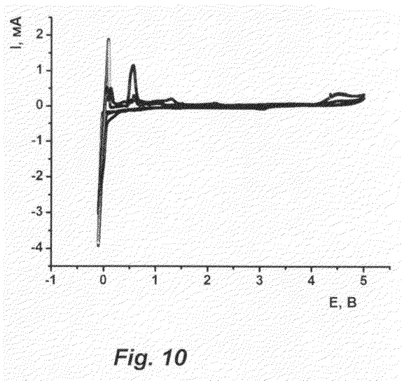

The scheme of the coating process of the present invention is shown in FIG. 1. A developmental system constructed for realization of this process is shown schematically in FIG. 2.

Based on research conducted using the developmental system described above, a process for Li₃PO₄ vaporization in an N₂ medium (nitrogen reaction gas) was developed. This process is designed to obtain “LiPon”, a solid electrolyte for lithium batteries.

The Li₃PO₄ vaporization process was implemented as follows. VC was pumped down with the PVS vacuum pump up to the marginal vacuum value monitored by GPM. N₂ reaction gas was fed to VC via GFS until the required pressure level was reached. This ensured continuous pumping of gas into VC and a constant and relatively clean atmosphere in the chamber. PVS system operated in the dynamic mode.

High voltage was supplied from HPSS to the electron gun (EG). The gun injected an electron beam (ER) into the vacuum chamber as shown. PSU FDS power-supply source was actuated, and power voltage was supplied to FDS focusing and deflecting systems. Electron beam focus was set on the substance to be vaporized in the crucible (C). Then the Li₃PO₄ heating and vaporization process was started. Li₃PO₄ vapor, while moving towards the substrate, interacted with nitrogen reaction gas. Thus, a LiPon coating was formed on the substrate. Substrate temperature was adjusted by the heater (H) and measured by the thermocouple TM1.

In the course of developing this LiPon-producing technology, a vacuum installation was used that included the following components. A cylindrical horizontally oriented stainless-steel vacuum chamber with water-cooling jacket served as vacuum chamber. The vacuum chamber inner diameter was 480 mm, with a length equaling 960 mm. Vacuum is generated by mechanical fore-vacuum pump and heated unit. Marginal permanent pressure in the chamber equals 6.6 10⁻⁴ Pascal. Vacuum was measured with thermocouple and ionization lamp.

A gas-discharge electron gun operating on the basis of a high-voltage smoldering discharge, and having a hollow anode and a cold cathode, was used as a vaporizer. As voltage is supplied to the gun's electrodes (anode and cathode), the high-voltage smoldering discharge is ignited. Discharged ions move toward the cathode, bombard it and knock electrons off the surface. The electrons are ejected up in the intra-electrode space, take up the form of electron beam, and exit into the space beyond the anode.

A special feature of the electron gun used is its capability to operate at a residual-gas pressure of up to 100 Pascal. This makes it possible to implement reaction-vaporization technology, which is important for production of LiPon. The electron gas-discharge gun operates at accelerating voltages of up to 30 kV, with electron-beam current of up to 1 A. The electron-beam diameter at the 0.707 level for the Gaussian distribution of beam-current density, in terms of cross-section, exceeds 2 mm. To focus and deflect the electronic beam, magnetic focusing and deflection systems are used. Use of a 3 kilowatt high-voltage power source made it possible to generate constant high voltage ranging from 0 to 20 kV with electron-beam current of up to 0.5 A.

A great deal of attention was paid to transfer of material from the solid phase to the vapor state. Due to a lack of information in available sources regarding the thermal characteristics of Li₃PO₄, the task of vaporization was difficult to achieve. Depending on the temperature and specific superficial power of the electron beam, three modes of its vaporization were specified: mode 1 is distinguished by low vaporization rate, mode 2 is high vaporization rate; mode 3 is so-called droplet vaporization. The process developed in the present invention allows elimination of droplet-forming vaporization.

A special feature of the LiPon producing technology of the present invention is vaporization in reaction-gas medium at pressure exceeding 10 Pascal. Under these conditions, N₂ was ionized on its way to the crucible containing the substance to be vaporized. This is a positive phenomenon in terms of LiPon production. It makes it possible to do without external additional ionizers (for example, HF source) for nitrogen reaction-gas and Li₃PO₄ vapor necessary for following through with chemical reaction of LiPon generation and its deposition onto the substrate surface.

We have experimentally demonstrated that Li₃ PO₄ coatings can be produced in a nitrogen medium with a gas-discharge electron gun used as a source of an electron beam. The vaporization rate Vₘ is determined as the mass of substance vaporized off a unit area of surface in the course of a unit time. Vaporization caused by cathode ray heating, theoretically equals

$$Vm = 4 , 4 \cdot {10}^{- 4} \cdot α \cdot {P}_{n} \sqrt{\frac{M}{T}} ,$$

where Vₘ is vaporization rate, g/(cm² sec);
α—vaporization coefficient (in an ideal case α=1);
Pₙ—vapor pressure, H/m², (pascal);
M—molar mass of the substance being vaporized, g;
T—vaporization temperature, K.

Vapor pressure to a first approximation depends on the temperature of the material being vaporized in the following way:

Pₙ=K₁·exp(−K₂/T),

where K₁, and K₂ coefficients depend on the material being vaporized

Schematically, a standard pressure-distribution at the time of cathode-ray vaporization is shown in FIG. 3.

Depending on the power of the electron beam N, the vaporization rate in the vapor-pressure range is determined by the following empiric expression

Vₘ=C·Nⁿ, (4)

where C and n are constant values depending on the characteristics of the material being vaporized and on vacuum-installation properties.

According to literature sources, cathode-ray vaporizers make it possible to reach the highest rates of substance-vaporization thanks to generation of high values of specific superficial density of energy on the surface of the vaporized substance (Nₛₚ<10⁸ . . . 10¹² watt/m²) unattainable through other methods used for vaporization.

In the case of cathode-ray vaporization, the density of vapor-flow coming out of a flat unit of vaporizer's surface is described by the equation

Φ(φ)=Φ₀·cosⁿφ,

where Φ(φ) is flow-density in the direction making a angle φ with the line normal to the vaporization surface; Φ₀ is density at φ=0; n>1 is a power index. Vapor flow spreads across the inner surface of a hemisphere (to be accurate, cosine curve of rotation). Coating thickness h on the inner surface of a hemisphere whose radius equals R, the hemisphere resulting from a point-like source with cosine vaporization-law, is proportional to volume of the vaporized material V in accordance with the expression

h(β,l,τ)=V(τ)/4πR²,

where, according to the spherical coordinate-system, β is longitude, l is latitude, τ is time. Knowing the coating thickness on the substrate, coating dimensions, density and co-ordinates of the substrate location over the crucible, one can determine the vaporization rate.

Coating deposition rate is determined in literature sources as the ratio of coating thickness and time. This does not provide complete information about the performance of the vapor source, as one can increase coating thickness, and deposition rate respectively, by several times by reducing distance to the crucible and selecting an optimal deposition angle.

Approximate coating deposition rates for cathode-ray technology falls within the 1 to 100 nm/sec range, the range for magnetron vapor deposition method being 1 to 30 nm/sec.

It should be noted that magnetrons perform well in terms of vapor deposition in the pressure range 1 to 10⁻² Pascal. Our gas-discharge electron guns also operate in this range. As pressure is increased, the vapor deposition rate for magnetrons drops according to the equation

V_{Hn}=k·P^{-m},

where k is a coefficient related to pressure unit; P is a working pressure; m>2 (usually m≈5).

To produce LiPon, it is necessary to vaporize lithium orthophosphate in the medium of nitrogen N₂ reaction gas, and it is advisable that reaction of their interaction proceed along the vapor path to the substrate. This condition is most favorably supported within nitrogen pressure-range of 1 to 50 Pascal. Magnetron operation within this range is troublesome, as there is instable operation, contraction of discharge and its transition to the arc shape. The number of punctures increases, and the vapor deposition rate decrease drastically. Operation of magnetrons in this range is either ineffective or impossible.

Vapor deposition rates that we have reached exceed those attained through the magnetron method by many fold.

The crucible construction with a cool-off radiator is shown in FIG. 4. The construction of this crucible makes it reusable. The metal crucible surface temperature at the time of lithium orthophosphate vaporization is 400° C., whereas temperature of the vaporized surface of the lithium orthophosphate exceeds 1200° C. So, introduction of the radiator lowers the temperature of “ceramic crucible—lithium orthophosphate” boundary, thus decreasing their interaction.

Another important purpose of this construction is as follows. When a non-conductor is bombarded with an electron beam, electron charge accumulates on its surface having no place to go due to high resistance of the non-conductor, that is, lithium orthophosphate. This charge defocuses and reflects beam's electrons. When a non-conductor surface gets warm, its temperature rises, its resistance decreases, and the charge bleeds away to the metal radiator. The heating process then intensifies abruptly and vaporization begins. The presence of a grounded metal screen makes it possible to bleed the charge off the superficial layer.

These heating stages can be distinguished visually by changes in luminescence. The following has been determined. When there is marginal power heating the non-conductor, neither vaporization, nor heating will occur below this level. Therefore, it is necessary to provide high power at the initial moment of heating, and then to ramp it up upon transition to another mode.

We considered both theoretically and experimentally the reasons of droplet formation in the vapor being vaporized, as well as methods of preventing droplets. The basic reason for their formation is as follows. The electron beam, as its specific power increases, begins to vaporize the lithium orthophosphate intensively and penetrate deeper into the crucible. Meanwhile, vapor is generated inside the crucible, and the liquid upper part of the substance closes (forms a closed covering above the solid phase with vapor trapped between).

The exiting vapor, as it passes through the fluid, generates drops and splashes. To prevent this from happening, the following is recommended:
selecting electron beam parameters in such a way that the beam does not get into the substance being vaporized;
scanning of electron beam across lithium orthophosphate surface;
operating electron gun in the impulse (pulsed) mode.

Substrate cleaning with impinging ions in a smoldering discharge plasma belongs to the most desirable treatment methods, as it makes it possible to treat substrates in the vacuum chamber just before the coating film is deposited. This helps prevent repeated substrate contamination. This kind of procedure presents a stable and easily controlled technological process.

In the case of ion treatment, cleaning occurs as a result of the following processes:
contamination desorption caused by ion and neutral particle impact;
photo desorption caused by ultra-violet radiation coming from the smoldering discharge area;
thermal desorption of contaminations, once heated by incoming ions;
change in structure and phase composition of substrate surface caused by impact of quick particles.

For treatment of substrates in a smoldering discharge under conditions of our experiment, high-voltage sealed lead must be introduced in the chamber. To this sealed lead a high-voltage power source is connected from the outside through a ballast resistor.

A scheme of the equipment for realization of the ion-plating method using a cathode-ray vaporizer is shown in FIG. 5. The parameters of the process, for example, could be as follows: Gas discharge in lithium orthophosphate and nitrogen vapor can ignite when located close to the crucible. Discharge current was 60 mA, accelerating voltage was 210 V. Discharge color and luminescence both changed. Ion current flowing onto the substrate at 1600 V voltage amounted to 20 mA.

The basic advantage of gas-discharge electron gun disclosed in the present invention is its capability to operate in low vacuum in the residual-gas pressure range from 10⁻² to 100 Pascal. This makes it possible to carry out reaction vapor deposition in the 1 to 50 Pascal pressure-range in which the known existing guns can not operate due to their construction. For their operation, special devices to take the electron beam out into high-pressure medium are required, thus eliminating their advantages under these conditions. Other gas-discharge electron guns, which operate under high vacuum, have difficulty to carry out reaction vapor deposition of LiPon onto a substrate at low pressure levels due to low nitrogen pressure. Therefore, additional ionization of nitrogen with a HF discharge is introduced and the coating is bombarded with a nitrogen-ion beam and so on.

Simplicity of equipment is a feature of the present scheme. For realization of this technology, a high-voltage power source and gas-discharge electron gun are necessary.

The gun ionizes nitrogen gas and vaporizes lithium orthophosphate on its way to the vaporizer. Orthophosphate interacts with nitrogen on its way to the substrate, thus producing a LiPon layer on the substrate. For realization of this process, the reduced pressure generated with a mechanical vacuum pump is sufficient.

The main advantages of the present invention over prior art are as follows:
1) The process takes place at nitrogen N₂ pressure levels that are significantly higher than those in the prior art, thus making it possible to intensify reactions of lithium phosphate with nitrogen: according our invention pressure level is 10 to 15 Pascal, whereas the prior art pressure level is 0.1 to 1 Pascal.
2) The vapor deposition process is realized in diffusion mode, thus providing for more regular coating on the substrate.
3) Interaction of the electronic beam with lithium phosphate vapor causes partial ionization of this vapor, thus making it possible to apply the ion-plating method.
4) The beam electrons reflected from the vaporizer cause extra ionization of the lithium phosphate vapor, thus making it possible to increase the vapor-deposition rate when ion-plating. Extra ionization of lithium phosphate vapor is accomplished by introducing a magnetic field that ensures spiral-motion of the reflected electrons.
5) The process is carried out in the impulse (pulsed) mode by means of impulses of the same polarity, yet different amplitude. This makes it possible to increase the degree of ionization of the nitrogen, thanks to the lowered energy of the beam electrons.
6) For evaporation of lithium phosphate without formation of droplets while maintaining high vapor density, two methods are used: 1) the electronic beam scans the surface of the material being vaporized not penetrating to the depth of droplet phase generation; 2) specific surface-density of energy in the electronic beam is decreased by defocusing the beam.
8) Management of electronic-beam parameters in evaporation mode is controlled by a feedback sensor recording vapor density and absence of the droplets in the vapor phase.
9) Both axial form and the planar form of the electronic beam impacting along the surface are used.

### EXAMPLES

It should be understood that the Examples described below are provided for illustrative purposes only and do not in any way define the scope of the invention

### Example 1

In the first example of the practice of the present invention, the initial material was Li₃PO₄, and the substrate was glass. The thickness of the solid phase deposited on the substrate during the process of the vapor deposition was 20 microns. Parameters of vapor deposition were as follows: electron gun voltage was 13 kV, and the gun current was 90 mA. The duration of the process was 3 minutes and the partial pressure of nitrogen within the chamber was 10⁻¹ millimeters of mercury. The temperature of the crucible was 800° C. The distance between crucible and the substrate was 10 cm.

Results of XRD analysis of the deposited solid phase are presented on FIG. 6 and confirm the amorphous structure of the deposited LiPon. The amorphous structure of the deposited LiPon provides high level of ionic conductivity of the solid electrolyte.

### Example 2

In the second example, the initial material was Li₃PO₄ and the substrate was glass. The thickness of the solid phase deposited on the substrate during the process of the vapor deposition was 10 micron. Parameters of vapor deposition were as follows: electron gun voltage was 7 kV, and the current of the gun was 120 mA. The duration of the process was 12 minutes. Argon pressure within the chamber was 10⁻¹ millimeters of mercury. The temperature of the crucible was 1000° C. The distance between crucible and substrate was 10 cm.

Material deposited on the substrate was removed from the substrate. The powder of the material was analyzed by XRD. Results of XRD analysis of the deposited solid phase shown in FIG. 7 confirm the crystalline structure of the deposited material. The material was Li₃PO₄.

### Example 3

In example 3, the initial material was Li₃PO₄. The substrate was platinum. The thickness of the LiPon deposited on the platinum during the process of the vapor deposition was 2 microns. Parameters of vapor deposition were as follows: the voltage of the electron gun was 7 kV, and the current of the gun was 200 mA. The duration of the process was 8 minutes. Partial pressure of nitrogen within the chamber was 10⁻¹ millimeters of mercury. The temperature of the crucible was 400° C.

The impedance characteristics of the Pt and Pt with deposited LiPon were investigated over the frequency operating range of 1 kHz to 200 kHz. Results are presented in FIG. 8. Results of the impedance investigation confirm that the LiPon deposited under the conditions of the present invention had ionic conductivity of 10⁻⁶ Ohm⁻¹ cm⁻¹.

### Example 4

In example 4, parameters of the vapor deposition of the LiPon, according the present invention are the same as in the Example 3. The potentiometric (cyclic voltametry) characteristics in non-aqueous electrolyte of the Pt electrode covered with deposited LiPon are shown in FIG. 10. These results were compared with the potentiometric (cyclic voltametry) characteristics in non-aqueous electrolyte on the Pt electrode without LiPon (FIG. 9). These results confirm that the thin film of solid electrolyte maintains electrochemical stability over a wide operating range.

### Closure

While various embodiments of the present invention have been shown and described, it will be apparent to those skilled in the art that many changes and modifications may be made without departing from the invention in its broader aspects. The appended claims are therefore intended to cover all such changes and modifications as fall within the true spirit and scope of the invention.

We claim:

1. Method for deposition of thin film solid electrolyte materials such as LiPon for energy storage devices and an apparatus for realization thereof comprising:
evaporation of Li₃PO₄ materials placed in a crucible, using an electron beam from a gas discharge electron gun, located in a vacuum chamber,
bleeding nitrogen (N₂) reaction gas into said vacuum chamber,
ionization of the said nitrogen gas in a high frequency discharge and subsequent interaction of Li₃PO₄ vapor with nitrogen ions and atoms resulting in generation of LiPon heating of the substrate, and
condensation of vapor on the surface of the substrate generating a film such as LiPon,
wherein the nitrogen N₂ reaction gas is ionized both in a high frequency discharge and by beam electrons generated by said gas-discharge electron gun, while the N₂ reaction gas is moving towards the material being evaporated, said process taking place at nitrogen N₂ pressure levels from 10 to 15 Pascal and,
wherein the vapor deposition process is realized in diffusion mode and the interaction of said electron beam with lithium phosphate vapor causes partial ionization of its vapor, and
wherein beam electrons, reflected from the vaporizer, cause additional ionization of said lithium phosphate vapor.

2. Method for deposition of thin film solid electrolyte materials such as LiPon for energy storage devices, as in claim 1, wherein additional ionization of lithium phosphate vapor is caused by introducing a magnetic field that causes spiral and/or helical motion of the reflected electrons.

3. Method for deposition of thin film solid electrolyte materials such as LiPon for energy storage as in claim 1, wherein said process is executed in pulse mode by means of pulses of the same polarity, at differing amplitudes.

4. Method for deposition of thin film solid electrolyte materials such as LiPon for energy storage devices as in claim 1, wherein for evaporation of lithium phosphate into the vapor phase at high vapor density, without formation of droplets, whereby said electron beam is scanned across the surface of the material being vaporized while not penetrating to the depth that leads to formation of droplets.

5. Method for deposition of thin film solid electrolyte as in claim 4, wherein the specific surface-density of energy in the electronic beam is decreased by defocusing said electron beam.

6. Method for deposition of thin film solid electrolyte materials such as LiPon for energy storage devices as in claim 1, wherein the management of the electron beam parameters in the evaporation mode are controlled by a feedback sensor that is sensing vapor density and absence of droplets.

7. Method for deposition of thin film solid electrolyte materials such as LiPon for energy storage as in claim 1, wherein both the axial form and the planar form of the electronic beam for impacting the surface of the material in the crucible are used.

8. Apparatus for the deposition of thin film solid electrolyte as in claims 1 through 7.
